(19) United States
(12) Patent Application Publication
(10) Pub. No.: US 2021/0064017 A1
(43) Pub. Date: Mar. 4, 2021

(54) ELECTRONIC COMPONENT REAL-TIME PROTECTION AND MONITORING NOTIFICATION SYSTEM

(71) Applicant: AMIDA TECHNOLOGY, INC., New Taipei City (TW)

(72) Inventor: Sen-Yu Cheng, New Taipei City (TW)

(21) Appl. No.: 16/928,387

(22) Filed: Jul. 14, 2020

(30) Foreign Application Priority Data
Aug. 30, 2019 (TW) 108131306

(51) Int. Cl. G05B 23/02; G01R 31/28

(52) U.S. Cl. CPC G05B 23/0254; G01R 31/2829; G05B 23/0297

(57) ABSTRACT

An electronic component real-time protection and monitoring notification system includes a primary controller and at least one protection notifier. The primary controller utilizes a feedback control circuit to control a control signal of an electronic component. Each protection notifier is connected in series with the primary controller and is independent of each other. When the parameter such as the temperature, voltage, or current of the controlled electrical component exceeds the safety requirements, each protection notifier clamps the primary controller from outputting the control signal in real-time and utilizes the photocoupler to issue a monitoring notification signal. By clamping the operation of the controlled electronic component, it is able to identify which part of the electronic component malfunctions. Through the aforementioned configuration, an effective and real-time monitoring function may be provided, thus decreasing the repairing costs.

### CROSS-REFERENCE TO RELATED APPLICATION

This application claims priority from Taiwan Patent Application No. 108131306, filed on Aug. 30, 2019, in the Taiwan Intellectual Property Office, the content of which is hereby incorporated by reference in its entirety for all purposes.

### BACKGROUND

### 1. Technical Field

The present disclosure relates to an electronic component real-time protection and monitoring notification system that utilizes protection notifiers independent from each other to monitor parameters of electronic components, such as voltage, current, temperature, etc.

### 2. Description of the Related Art

In daily life, when an electronic component is not functioning normally, the user would try to manually power off and then restart the electronic component to make it function normally again. Although the electronic component may be back to normal, the user still does not know which part of the electronic component causes the malfunction. Not until the electronic component completely stops functioning does the user seek for repair from professionals. If the user is able to identify which part of the electronic component is malfunctioning, only part of the electronic component is required to be replaced, thus decreasing the repairing costs.

With the advancement of technology, existing techniques have been developed for a monitoring device such as RTC (Real Time Clock) of a microprocessor to monitor errors within the microprocessor. However, only part of the internal electronic component is detected, instead of overall detection on the elements/parts of the electronic component. Moreover, it is still difficult to identify which part of the electronic component in malfunctioning for the existing monitoring devices.

Accordingly, the inventor of the present disclosure has designed an electronic component real-time protection and monitoring notification system in an effort to tackle deficiencies in the prior art and further to enhance the implementation and application in industries.

### SUMMARY

According to the problems mentioned above, the objective of the present disclosure is to provide an electronic component real-time protection and monitoring notification system to solve the problems that may be encountered in the prior art.

Based on the above, the present disclosure provides an electronic component real-time protection and monitoring notification system, including a primary controller and at least one protection notifier. The primary controller includes a pre-operational amplifier and a post-operational amplifier. Both the pre-operational amplifier and the post-operational amplifier have a positive end, a negative end, and an output end. A node is disposed between the output end of the pre-operational amplifier and the positive end of the post-operational amplifier. The node is connected to the output end and the negative end of the pre-operational amplifier and the positive end of the post-operational amplifier. The positive end of the pre-operational amplifier receives a primary threshold value and a primary measurement value opposite in polarity to the primary threshold value and the pre-operational amplifier outputs an error signal accordingly. The post-operational amplifier outputs a control signal to an electronic component to be protected and monitored according to the error signal.

Each protection notifier is cascaded and connected to the node and includes a positive circuit and a negative circuit. Both the positive circuit and the negative circuit include a monitoring operational amplifier, a photocoupler, and a diode. The monitoring operational amplifier has a positive end, a negative end, and an output end. The output end of the monitoring operational amplifier is connected to the diode and the photocoupler. The diode is connected to the negative end of the monitoring operational amplifier and the photocoupler is connected to the node. The positive end of the monitoring operational amplifier receives a secondary threshold value and a secondary measurement value opposite in polarity to the secondary threshold value. When the monitoring operational amplifier of the positive circuit and the negative circuit operates to determine a difference value between the secondary threshold value and the secondary measurement value to be substantially equal to zero such that the diode of the positive circuit or the negative circuit is reverse-biased, the photocoupler of the positive circuit or the negative circuit is turned on to issue a monitoring notification signal, and the post-operational amplifier clamps outputting of the control signal in real-time, clamps the operation of the electronic component, and identifies which part of the electronic component malfunctions. Through the aforementioned configuration, it is able to identify which part of the electronic component malfunctions, thus decreasing the repairing costs.

Preferably, the output end and the negative end of the post-operational amplifier are connected to each other.

Preferably, when the monitoring operational amplifier of the positive circuit or the negative circuit operates to determine the difference value between the secondary threshold value and the secondary measurement value to be substantially larger than zero such that the diode of the positive circuit or the negative circuit is forward-biased, and the photocoupler of the positive circuit or the negative circuit is turned off.

Preferably, the electronic component real-time protection and monitoring notification system of the present disclosure further includes a primary differential amplifier, wherein the primary differential amplifier is connected to the electronic component and a port of the positive end of the pre-operational amplifier that receives the primary threshold value, and the primary differential amplifier converts the polarity of the primary measurement value to be opposite to the polarity of the primary threshold value.

Preferably, each of the positive circuits and each of the negative circuits are respectively connected to a positive differential amplifier and a negative differential amplifier, both the positive differential amplifier and the negative differential amplifier are connected to the electronic component, and both the positive differential amplifier and the negative differential amplifier convert the polarity of each of the secondary measurement values to be opposite to the polarity of the secondary threshold value.

Preferably, the primary measurement value is a primary parameter for measuring the electronic component, each of the secondary measurement values is a secondary parameter for measuring the electronic component, and the primary parameter is different from each of the secondary parameters.

Preferably, one of the positive circuit and the negative circuit is selected for operation according to the polarity of the corresponding secondary parameter.

Preferably, the secondary parameters are different from each other.

Preferably, if the secondary parameter is a temperature value, the electronic component real-time protection and monitoring notification system of the present disclosure further includes a thermocouple converter, and the thermocouple converter is connected between the electronic component and the positive circuit or between the electronic component and the negative circuit, in order to convert the temperature value to an electric signal same as the secondary threshold value.

Preferably, if the primary parameter or the secondary parameter is a current value, the electronic component real-time protection and monitoring notification system of the present disclosure further includes a current-to-voltage converter, the current-to-voltage converter is connected between the electronic component and the positive circuit, between the electronic component and the negative circuit, or between the electronic component and the primary controller, in order to convert the current value into an electric signal same as the secondary threshold value or the primary threshold value.

Preferably, the monitoring notification signals are independent of each other.

Preferably, the electronic component real-time protection and monitoring notification system of the present disclosure further includes a microprocessor, wherein the microprocessor is connected to the primary controller and connected to the photocoupler of the positive circuit and the negative circuit of each of the protection notifiers.

Preferably, when the microprocessor receives the monitoring notification signal, the microprocessor sends a stop signal to the primary controller, and the post-operational amplifier stops outputting the control signal.

As mentioned above, through the notifications from the primary controller and each protection notifier, the electronic component real-time protection and monitoring notification system may clamp the operation of the electronic component in real-time and identify which part of the electronic component malfunctions, thus decreasing the repairing costs.

### BRIEF DESCRIPTION OF THE DRAWINGS

FIG. 1 is a configuration diagram of the first embodiment of the electronic component real-time protection and monitoring notification system according to the present disclosure.

FIG. 2 is a circuit diagram of the first embodiment of the electronic component real-time protection and monitoring notification system according to the present disclosure.

FIG. 3 is a circuit diagram of the second embodiment of the electronic component real-time protection and monitoring notification system according to the present disclosure.

FIG. 4 is a circuit diagram of the primary differential amplifier of the second embodiment of the electronic component real-time protection and monitoring notification system according to the present disclosure.

FIG. 5 is a waveform diagram of the second embodiment of the electronic component real-time protection and monitoring notification system according to the present disclosure.

FIG. 6 is a configuration diagram of the third embodiment of the electronic component real-time protection and monitoring notification system according to the present disclosure.

### DESCRIPTION OF THE PREFERRED EMBODIMENTS

The advantages, features, and technical methods of the present disclosure are to be explained in detail with reference to the exemplary embodiments and the drawings for a better understanding of the present disclosure. Moreover, the present disclosure may be realized in different forms, and should not be construed as being limited to the embodiments set forth herein. Conversely, for a person of ordinary skill in the art, the embodiments provided shall make the present disclosure convey the scope more thoroughly, comprehensively, and completely. In addition, the present disclosure shall be defined only by the appended claims.

It should be noted that although the terms “first,” “second,” and the like may be used in the present disclosure to describe various elements, components, regions, layers and/or parts, these elements, components, regions, layers and/or parts should not be limited by these terms. These terms are only used to distinguish one element, component, region, layer, and/or part from another element, component, region, layer, and/or part. Hence, the “first element”, “first component”, “first region”, “first layer”, and/or “first part” discussed hereinafter may be referred to as “second component”, “second region”, “second layer”, and/or “second part” without departing from the teachings of the present disclosure.

In addition, the terms “include” and/or “contain” are used to indicate the presence of features, regions, entirety, steps, operations, elements and/or components, but may not exclude the presence or addition of one or more of other features, regions, entirety, steps, operations, elements, components, and/or combinations thereof.

Unless otherwise defined, all terms (including technical and scientific terms) used in the present disclosure have the same meaning as those commonly understood by a person of ordinary skill in the art. It should be further understood that, unless explicitly defined herein, the terms such as those defined in commonly used dictionaries should be interpreted as having definitions consistent with their meaning in the context of the related art and the present disclosure, and should not be construed as idealized or overly formal.

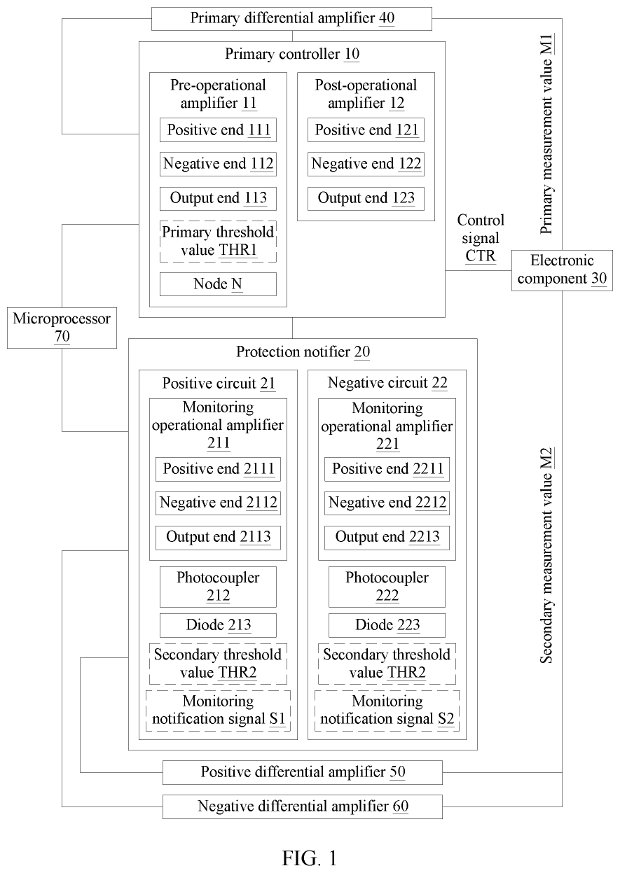

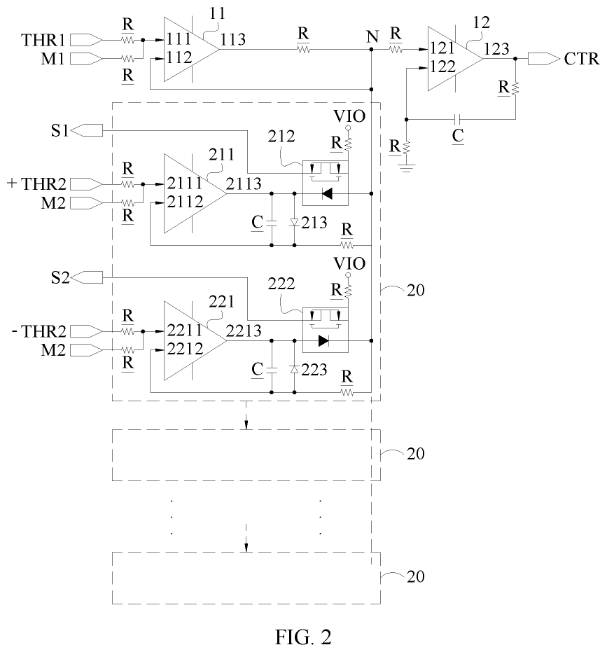

Referring to FIG. 1 and FIG. 2, the figures are respectively a configuration diagram of the first embodiment of the electronic component real-time protection and monitoring notification system according to the present disclosure, and a circuit diagram of the first embodiment of the electronic component real-time protection and monitoring notification system according to the present disclosure. As shown in FIG. 1 and FIG. 2, the electronic component real-time protection and monitoring notification system of the present disclosure includes a primary controller 10, at least one protection notifier 20, an electronic component 30, a primary differential amplifier 40, a positive differential amplifier 50, a negative differential amplifier 60, and a microprocessor 70. The primary controller 10 includes a pre-operational amplifier 11 and a post-operational amplifier 12. The pre-operational amplifier 11 has a positive end 111, a negative end 112, and an output end 113. The post-operational amplifier 12 has a positive end 121, a negative end 122, and an output end 123. A node N is disposed between the output end 113 of the pre-operational amplifier 11 and the positive end of the post-operational amplifier 12. The node N is connected to the output end 113 and the negative end 112 of the pre-operational amplifier 11 and the positive end 121 of the post-operational amplifier 12. The output end 123 and the negative end 122 of the post-operational amplifier 12 are connected to each other. The pre-operational amplifier 11 and the post-operational amplifier 12 are negative feedback amplifiers. The positive end 111 of the pre-operational amplifier 11 receives a primary threshold value THR1 and a primary measurement value M1 opposite in polarity to the primary threshold value THR1, and the pre-operational amplifier 11 outputs an error signal accordingly. The post-operational amplifier 12 outputs a control signal CTR to an electronic component 30 to be protected and monitored according to the error signal in order to allow the electronic component 30 operate to perform its function.

The primary differential amplifier 40 is connected to the electronic component 30 and a port of the positive end 111 of the pre-operational amplifier 11 that receives the primary threshold value M1, and the primary differential amplifier 40 converts the polarity of the primary measurement value M1 to be opposite to the polarity of the primary threshold value THR1. The positive differential amplifier 50 and the negative differential amplifier 60 are respectively connected to the corresponding positive circuit 21 and the negative circuit 22, both the positive differential amplifier 50 and the negative differential amplifier 60 are connected to the electronic component 30, and both the positive differential amplifier 50 and the negative differential amplifier 60 convert the polarity of each of the secondary measurement values M2 to be opposite to the polarity of the secondary threshold value THR2. The microprocessor 70 is connected to the primary controller 10 and connected to the photocouplers 212 and 222 of the positive circuit 21 and the negative circuit 22 of the protection notifier 20.

Each protection notifier 20 is cascaded and connected to the node N and includes a positive circuit 21 and a negative circuit 22. The positive circuit 21 includes a monitoring operational amplifier 211, a photocoupler 212, and a diode 213. The negative circuit 22 includes a monitoring operational amplifier 221, a photocoupler 222, and a diode 223. The monitoring operational amplifier 211 of the positive circuit 21 has a positive end 2111, a negative end 2112, and an output end 2113. The output end 2113 of the monitoring operational amplifier 211 of the positive circuit 21 is connected to the diode 213 and the photocoupler 212. The diode 213 of the positive circuit 21 is connected to the negative end 2113 of the monitoring operational amplifier 221 and the photocoupler 212 of the positive circuit 21 is connected to the node N. The positive end 2111 of the monitoring operational amplifier 211 of the positive circuit 21 is connected to a secondary threshold value THR2 and a secondary measurement value M2 opposite in polarity to the secondary threshold value THR2. The monitoring operational amplifier 221 of the negative circuit 22 has the positive end 2211, the negative end 2212, and the output end 2213. The output end 2213 of the monitoring operational amplifier 221 of the negative circuit 22 is connected to the diode 223 and the photocoupler 222. The diode 223 of the negative circuit 22 is connected to the negative end 2213 of the monitoring operational amplifier 221 and the photocoupler 222 of the negative circuit 22 is connected to the node N. The positive end 2211 of the monitoring operational amplifier 221 of the negative circuit 22 is connected to a secondary threshold value THR2 and a secondary measurement value M2 opposite in polarity to the secondary threshold value THR2.

When the monitoring operational amplifier 211 or 221 of the positive circuit 21 or the negative circuit 22 operates to determine a difference value between the secondary threshold value THR2 and the secondary measurement value M2 to be substantially equal to zero such that the diode 213 or 223 of the positive circuit 21 or the negative circuit 22 is reverse-biased, and the photocoupler 212 or 222 of the positive circuit 21 or the negative circuit 22 is turned on to issue a monitoring notification signal S1 or S2 to the microprocessor 70; the microprocessor 70 receives the monitoring notification signal S1 or S2 and sends a stop signal to the primary controller 10, the post-operational amplifier 12 stops outputting the control signal CTR, and the electronic component 30 stops operating and the microprocessor 70 identifies which part of the electronic component 30 malfunctions according to the monitoring notification signal S1 or S2 received. When the monitoring operational amplifier 211 or 221 of the positive circuit 21 or the negative circuit 22 operates to determine the difference value between the secondary threshold value THR2 and the secondary measurement value M2 to be substantially larger than zero such that the diode 213 or 223 of the positive circuit 21 or the negative circuit 22 is forward-biased, and the photocoupler 212 or 222 of the positive circuit 21 or the negative circuit 22 is turned off. The post-operational amplifier 12 maintains outputting the control signal CTR to the electronic component 30. Through the aforementioned configuration, it is able to identify which part of the electronic component malfunctions, thus decreasing the repairing costs.

It should be noted that the positive end 111 and the output end 113 of the pre-operational amplifier 11 are both configured with a resistance R to appropriately adjust the primary threshold value THR1 and the primary measurement value M1; the positive end 121, the negative end 122, and the output end 123 of the post-operational amplifier 12 are configured with a resistance R or a capacitance C to properly adjust the control signal CTR. The positive ends 2111 and 2211 of the monitoring operational amplifier 211 of the positive circuit 21 and the monitoring operational amplifier 221 of the negative circuit 22 are configured with a resistance R to appropriately adjust the secondary threshold value THR2 and the secondary measurement value M2. The diodes 213 and 223 of the monitoring operational amplifier 211 of the positive circuit 21 and the monitoring operational amplifier 221 of the negative circuit 22 are also connected in parallel with a capacitance C, and the photocouplers 212 and 222 are also connected to the power supply end VIO (usually the operating voltage of the microprocessor 70) to enable the photocouplers 212 and 222 to operate normally. The aforementioned configuration is an example and the configuration of a resistance R and a capacitance C may be adjusted according to actual needs without being limited in the scope exemplified by the present disclosure.

Specifically, the primary measurement value M1 is a primary parameter for measuring the electronic component 30, each of the secondary measurement values M2 is a secondary parameter for measuring the electronic component 30, and the primary parameter is different from each of the secondary parameters. For instance, the primary parameter may be voltage, the two secondary parameters may be electrical current and temperature, and the number of secondary parameters may be adjusted according to the parameters of the electronic component 30 to be measured. Therefore, the number of protection notifiers 20 should also be adjusted according to actual needs without being limited in the scope exemplified by the present disclosure.

In addition, the polarity of the secondary parameter may be negative or positive. If the polarity of the secondary parameter is negative, the secondary measurement value M2 is sent to the negative circuit 22, and the negative circuit 22 operates accordingly; if the polarity of the secondary parameter is positive, the secondary measurement value M2 is sent to the positive circuit 21, and the positive circuit 21 operates accordingly. In other words, one of the positive circuit 21 and the negative circuit 22 is selected for operation according to the polarity of the corresponding secondary parameter M2.

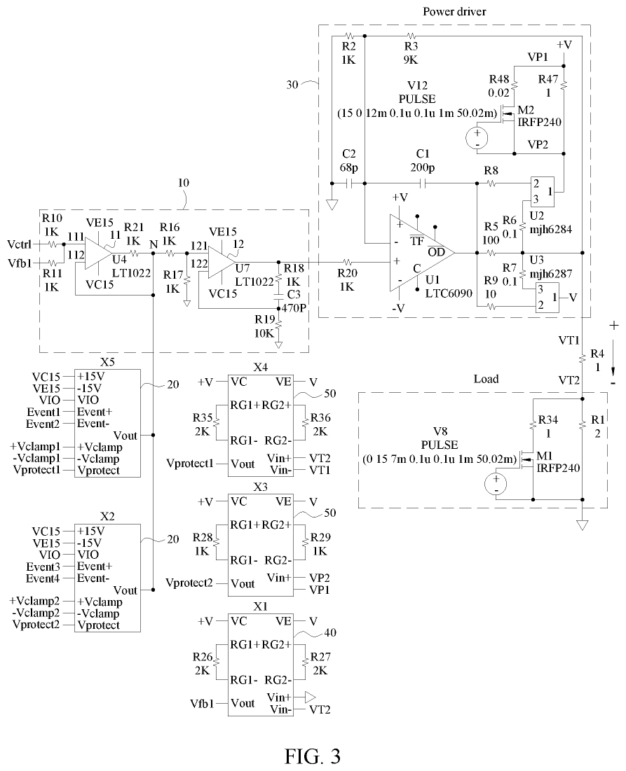

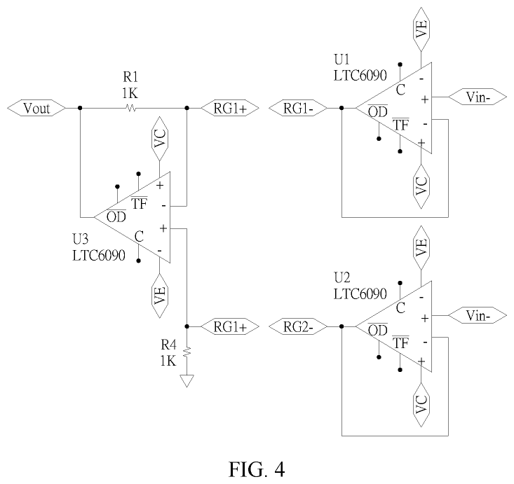

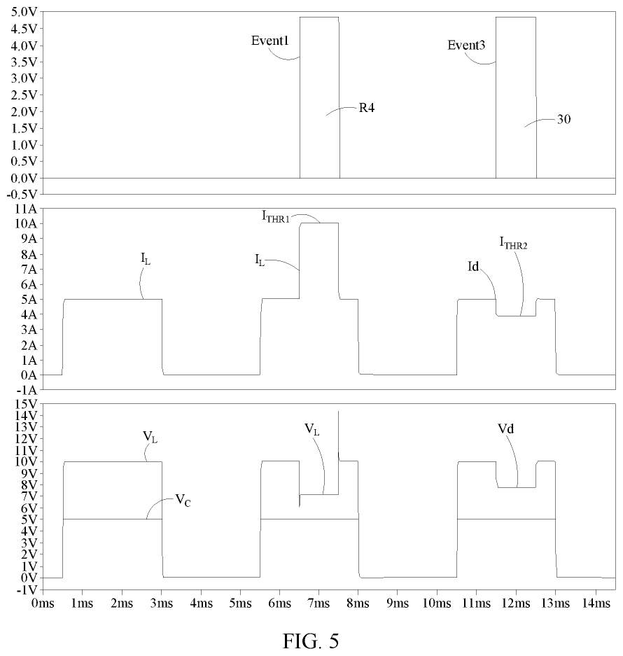

Referring to FIG. 3, FIG. 4, and FIG. 5, the figures are respectively a circuit diagram of the second embodiment of the electronic component real-time protection and monitoring notification system according to the present disclosure, a circuit diagram of the primary differential amplifier of the second embodiment of the electronic component real-time protection and monitoring notification system according to the present disclosure, and a waveform diagram of the second embodiment of the electronic component real-time protection and monitoring notification system according to the present disclosure. In the embodiment, the configuration of the same components with the same numerals is similar to that described above, so the similar descriptions are not to be described herein.

As shown in FIG. 3, the electronic component 30 is a power driver, and the node N of the primary controller 10 is connected to the Vout ports of the two protection notifiers 20 respectively. The monitoring notification signal S1 of one of the two protection notifiers 20 (X5) is Event1 or Event2 sent from the Event+ port or Event− port (That is, the monitoring notification signal S1 of the protection notifier 20 (X5) may be denoted as Event1 or Event2). The monitoring notification signal S1 of another protection notifier 20 (X2) is Event3 or Event4 sent from the Event+ port or Event− port (That is, the monitoring notification signal M of the protection notifier 20 (X2) may be denoted as Event3 or Event4). The Vprotect port of the protection notifier 20 (X5) receiving the Vprotect1 voltage is connected to the Vout port of the positive differential amplifier 50 (X4) which sends the Vprotect1 voltage (That is, the Vprotect1 voltage is the secondary measurement value M2). The Vprotect port of the protection notifier 20 (X2) receiving the Vprotect2 voltage is connected to the Vout port of the positive differential amplifier 50 (X3) which sends the Vprotect2 voltage (That is, the Vprotect2 voltage is the secondary measurement value M2). The port of the positive end 111 of the pre-operational amplifier 11 receiving the Vfb1 voltage is connected to the port of the primary differential amplifier 40 which sends the Vfb1 voltage.

Specifically, the +Vclamp port or −Vclamp port of the protection notifier 20 (X5) receives the secondary threshold value THR2 (may also be denoted as +Vclamp1 or −Vclamp1), the +Vclamp port or −Vclamp port of the protection notifier 20 (X2) receives the secondary threshold value THR2 (may also be denoted as +Vclamp2 or −Vclamp2), and the secondary threshold value THR2 of the protection notifier 20 (X5) is different from that of the protection notifier 20 (X2). The port Vctr1 at which the positive end 111 of the pre-operational amplifier 11 receives the voltage receives the primary threshold value THR1. The Vin+ port of the positive differential amplifier 50 (X4) receives the VT2 voltage of the resistance R4, and the Vin− port thereof receives the VT1 voltage of the resistance R4. Since the VT1 voltage is larger than the VT2 voltage, the Vprotect1 voltage (secondary measurement value M2) may be opposite in polarity to the corresponding secondary threshold value THR2, thus obtaining the difference value between the Vprotect1 voltage and the secondary threshold value THR2. The Vin+ port of the positive differential amplifier 50 (X) receives the VP2 voltage of the resistance R47, and the Vin− port thereof receives the VP1 voltage of the resistance R47. Since the VP1 voltage is larger than the VP2 voltage, the Vprotect2 voltage (secondary measurement value M2) may be opposite in polarity to the corresponding secondary threshold value THR2, thus obtaining the difference value between the Vprotect2 voltage and the secondary threshold value THR2. The Vin+ port of the primary differential amplifier 40 is grounded and the Vin− port thereof receives the VT2 voltage of the resistance R4. Therefore, the Vfb1 voltage may be opposite in polarity to the primary threshold value THR1, thus obtaining the difference value between the Vfb1 voltage and the primary threshold value THR1.

It should be noted that the protection notifier 20 (X5) and the protection notifier 20 (X2) also include a positive circuit 21 and a negative circuit 22 as shown in FIG. 2. The positive circuit and the negative circuit are represented by components only for the purpose of simplifying the complexity of the circuit. The load voltage V_{L} is the difference value between VT1 and VT2. The load current I_{L} is the current flowing through the resistance R4. The voltage V_{d} of the internal components of the power driver is the difference value between VP1 and VP2 (cross-voltage difference value of the resistance R47). The current I_{d} of the internal components of the power driver is the current flowing through the resistance R47. The voltages of VC15 and VE15 are supply voltages for normal operation of the positive circuit 21, the negative circuit 22, the pre-operational amplifier 11, and the post-operational amplifier 12.

As shown in FIG. 4, the primary differential amplifier 40 includes a plurality of operational amplifiers LTC6090 having corresponding resistances connected. The plurality of resistances are configured to change the magnification rates of the plurality of operational amplifiers. The positive differential amplifier 50 (X4) and the positive differential amplifier 50 (X3) have the same configuration as that of the primary differential amplifier 40. The repeated description is therefore omitted herein.

As shown in FIG. 5, with reference to FIG. 1 to FIG. 3, the command voltage V_{c} is set to be 5V first to obtain the load voltage V_{L} as 10V. Through the load resistance R47, the monitoring load current I_{THR1} is set to be 10 A, and the monitoring voltage of the internal monitoring component (resistance R47) of the power driver is set to be 2V. During the normal operation period from 0 msec to 5 msec, the command voltage V_{c} is maintained at 5V, the load current I_{L} flowing through the resistance R1 (2Ω) is 5 A, and the current I_{d} flowing through the internal monitoring component (resistance R47) of the power driver is also 5 A. However, the monitoring voltage of the internal monitoring component (resistance R47) of the power driver does not exceed 2V. The internal components in the power driver are protected by threshold voltage, so the current flowing through internal components in the power driver is 5 A under normal operation of the power driver (set to be 2V).

During the period from 5 msec to 10 msec, the load is simulated to be short-circuited at 6.5 msec to 7.8 msec to increase the load current I_{L} to more than 10 A (exceeding the setting for the monitoring load current). The present disclosure actively clamps the input of the power driver at the moment so that the load voltage V_{L} drops to less than 10V and the load current I_{L} does not exceed 10 A. In the meantime, the protection notifier 20 (X5) of FIG. 3 starts operating, and the positive circuit 21 of the protection notifier 20 (X5) operates to calculate the error between the Vprotect1 voltage and the corresponding secondary threshold value THR2 (protection setting value +Vclamp1) in real-time. Due to the occurrence of a short circuit, the error of the corresponding secondary threshold value THR2 (protection setting value +Vclamp1) of the Vprotect1 voltage is less than or equal to zero. That is, the occurrence of a short circuit causes the output of the monitoring operational amplifier 211 of the positive circuit 21 to approach zero. The diode 213 of the positive circuit 21 is reverse-biased, and the internal diode of the photocoupler 212 of the positive circuit 21 is forward-biased to issue a monitoring notification signal Event1. Since the output of the monitoring operational amplifier 211 approaches zero at the moment, the operation of the primary controller 10 is clamped, thus clamping the output of the control signal CTR. In the meantime, the photocoupler 212 sends a monitoring notification signal Event1 to the microprocessor 70, and the microprocessor 70 receives the monitoring notification signal Event1 and may decide whether to send a stop signal to the primary controller 10. The post-operational amplifier 12 controls the output of the control signal CTR accordingly, and the electronic component 30 operates accordingly.

During the period from 10 msec to 15 msec, the internal monitoring component (resistance R47) of the power driver is simulated to malfunction from 11.5 msec to 12.5 msec due to degradation, resulting in an increase in the resistance value of the resistance R47. When the same load current I_{L} is 5 A, the cross voltage of the internal monitoring component (resistance R47) exceeds the monitoring set voltage of the power driver by 2V. The present disclosure actively clamps the input of the power driver at the moment, so that the cross voltage of the internal monitoring component (resistance R47) does not exceed 2V, and the load voltage V_{L} drops simultaneously to less than 10V. In the meantime, the protection notifier 20 (X2) of FIG. 3 starts operating, and the positive circuit 21 of the protection notifier 20 (X2) operates the error of the Vprotect2 voltage and the corresponding secondary threshold value THR2 (protection setting value +Vclamp2) in real-time. The degradation and malfunction lead to the Vprotect2 voltage to become larger, so that the error of the Vprotect2 voltage operated by the positive circuit 21 and the corresponding secondary threshold value THR2 (protection setting value +Vclamp2) approaches zero. That is, the output of the monitoring operational amplifier 211 of the positive circuit 21 approaches zero. The diode 213 of the positive circuit 21 is reverse-biased, and the internal diode of the photocoupler 212 of the positive circuit 21 is forward-biased to issue a monitoring notification signal Event3. Since the output of the monitoring operational amplifier 211 equals zero at the moment, the operation of the primary controller 10 is clamped, thus clamping the output of the control signal CTR. In the meantime, the photocoupler 212 sends a monitoring notification signal Event3 to the microprocessor 70, and the microprocessor 70 receives the monitoring notification signal Event3 and may decide whether to send a stop signal to the primary controller 10. The post-operational amplifier 12 controls the output of the control signal CTR accordingly, and the electronic component 30 operates accordingly.

The output voltage range of the positive polarity is discussed on the aforementioned abnormal events only. When the output voltage range of the negative polarity is abnormal, the negative circuit 22 of the protection notifier 20 (X2, X5) is switched to complete the same protection operation mode. The only difference is the opposite in polarity, so the similar descriptions are not to be described herein.

It should be noted that the secondary measurement value M2 required by the positive circuit 21 and the negative circuit 22 may be, for example, the same unit of voltage; however, the corresponding detected components are different, so parameters of different components are detected. Therefore, the positive circuit 21 and the negative circuit 22 may detect the parameters of different components and operate in the same unit of voltage. This is only an example without limiting the scope of the disclosure to be protected.

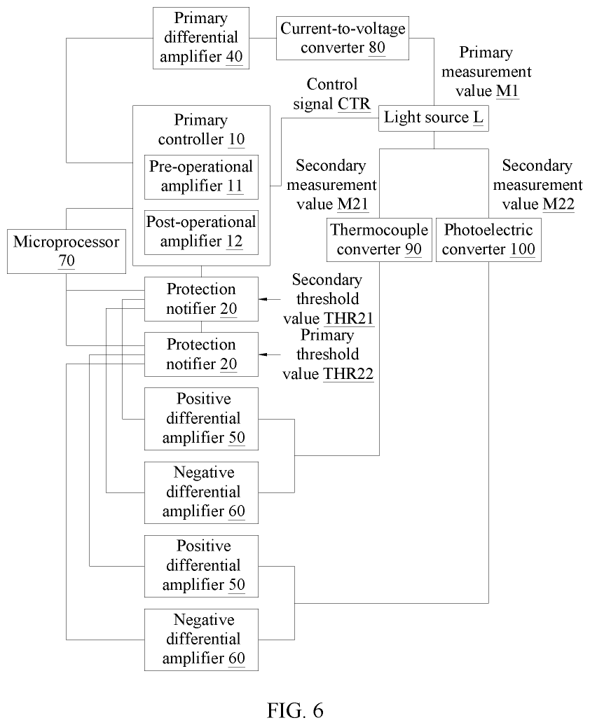

Referring to FIG. 6, the figure is a configuration diagram of the third embodiment of the electronic component real-time protection and monitoring notification system according to the present disclosure. In the embodiment, the configuration of the same components with the same numerals is similar to that described above, so the similar descriptions are not to be described herein.

As shown in FIG. 6, the electronic component real-time protection and monitoring notification system of the present disclosure relates to the monitoring of light source L. Correspondingly, the electronic component real-time protection and monitoring notification system of the present disclosure includes a current-to-voltage converter 80, a thermocouple converter 90, and a photoelectric converter 100 to detect the current, temperature, and light flux of the light source L. The primary threshold value THR1 and the secondary threshold values THR21 and THR22 are denoted as voltage values. The current-to-voltage converter 80 is connected between the primary differential amplifier 40 and the light source L to convert the current (primary measurement value M1) into a voltage value. The thermocouple converter 90 is connected to the light source L, the positive differential amplifier 50, and the negative differential amplifier 60 to convert the temperature (secondary measurement value M21) into a voltage value. The photoelectric converter 100 is connected to the light source L, the positive differential amplifier 50, and the negative differential amplifier 60 to convert the light flux (secondary measurement value M22) into a voltage value.

Specifically, the current-to-voltage converter 80 converts the primary measurement value M1 into a corresponding voltage and sends it to the primary differential amplifier 40, the primary differential amplifier 40 applies polarity conversion to the primary measurement M1 which has been converted to voltage and sends it to the primary controller 10, and the primary controller 10 outputs a control signal CTR to control the current of the light source L accordingly.

The thermocouple converter 90 converts the secondary measurement value M21 into a corresponding voltage value and sends it to the positive differential amplifier 50 or the negative differential amplifier 60, and the positive differential amplifier 50 or the negative differential amplifier 60 applies polarity conversion to the secondary measurement value M21 which has been converted into voltage and sends it to the protection notifier 20. The protection notifier 20 operates to determine the difference value between the secondary threshold value THR21 and the secondary measurement value M21. If the difference value between the secondary threshold value THR21 and the secondary measurement value M21 is zero, the diode 213 or 223 of the positive circuit 21 and the negative circuit 22 is reverse-biased such that the photocoupler 212 or 222 of the positive circuit 21 or the negative circuit 22 is turned on to issue a monitoring notification signal S1 or S2 to the microprocessor 70; the microprocessor 70 receives the monitoring notification signal S1 or S2 and sends a stop signal to the primary controller 10, the post-operational amplifier 12 stops outputting the control signal CTR, and the light source L stops operating. If the difference value between the secondary threshold value THR21 and the secondary measurement value M21 is larger than zero, the diode 213 or 223 of the positive circuit 21 and the negative circuit 22 is forward-biased such that the photocoupler 212 or 222 of the positive circuit 21 or the negative circuit 22 is turned off; the post-operational amplifier 12 maintains outputting the control signal CTR to the light source.

The photoelectric converter 90 converts the secondary measurement value M22 into a corresponding voltage value and sends it to the positive differential amplifier 50 or the negative differential amplifier 60, and the positive differential amplifier 50 or the negative differential amplifier 60 applies polarity conversion to the secondary measurement value M22 which has been converted into voltage and sends it to the protection notifier 20. The protection notifier 20 operates to determine the difference value between the secondary threshold value THR22 and the secondary measurement value M22. If the difference value between the secondary threshold value THR22 and the secondary measurement value M22 is zero, the diode 213 or 223 of the positive circuit 21 and the negative circuit 22 is reverse-biased such that the photocoupler 212 or 222 of the positive circuit 21 or the negative circuit 22 is turned on to issue a monitoring notification signal S1 or S2 to the microprocessor 70; the microprocessor 70 receives the monitoring notification signal S1 or S2 and sends a stop signal to the primary controller 10, the post-operational amplifier 12 stops outputting the control signal CTR, and the light source L stops operating. If the difference value between the secondary threshold value THR22 and the secondary measurement value M22 is larger than zero, the diode 213 or 223 of the positive circuit 21 and the negative circuit 22 is forward-biased such that the photocoupler 212 or 222 of the positive circuit 21 or the negative circuit 22 is turned off; the post-operational amplifier 12 maintains outputting the control signal CTR to the light source L.

Specifically, the monitoring notification signal M corresponding to the protection notifier 20 having the secondary threshold value THR21 and the monitoring notification signal S1 or S2 corresponding to the protection notifier 20 having the secondary threshold value THR22 are independent of each other and do not affect each other. That is, the monitoring notification signals M are independent of each other.

Accordingly, the electronic component real-time protection and monitoring notification system of the present disclosure stops the operation of the electronic component 30 in real-time through the notifications of the primary controller 10 and each protection notifier 20. In summary, the electronic component real-time protection and monitoring notification system of the present disclosure has the advantages as mentioned above and is able to identify which part of the electronic component malfunctions.

The above description is merely illustrative rather than restrictive. Any equivalent modifications or alterations without departing from the spirit and scope of the present disclosure are intended to be included in the following claims.

What is claimed is:

1. An electronic component real-time protection and monitoring notification system, including:
a primary controller comprising a pre-operational amplifier and a post-operational amplifier, both the pre-operational amplifier and the post-operational amplifier having a positive end, a negative end, and an output end, a node being disposed between the output end of the pre-operational amplifier and the positive end of the post-operational amplifier, the node being connected to the output end and the negative end of the pre-operational amplifier and the positive end of the post-operational amplifier, the positive end of the pre-operational amplifier receiving a primary threshold value and a primary measurement value opposite in polarity to the primary threshold value and the pre-operational amplifier outputting an error signal accordingly, and the post-operational amplifier outputting a control signal to an electronic component to be protected and monitored according to the error signal; and
at least one protection notifier cascaded and connected to the node and each of the at least one protection notifier comprising a positive circuit and a negative circuit, both the positive circuit and the negative circuit comprising a monitoring operational amplifier, a photocoupler and a diode, the monitoring operational amplifier having a positive end, a negative end and an output end, the output end of the monitoring operational amplifier being connected to the diode and the photocoupler, the diode being connected to the negative end of the monitoring operational amplifier, and the photocoupler being connected to the node, and the positive end of the monitoring operational amplifier receiving a secondary threshold value and a secondary measurement value opposite in polarity to the secondary threshold value;
wherein when the monitoring operational amplifier of the positive circuit and the negative circuit operates to determine a difference value between the secondary threshold value and the secondary measurement value to be substantially equal to zero such that the diode of the positive circuit or the negative circuit is reverse-biased, the photocoupler of the positive circuit or the negative circuit is turned on to issue a monitoring notification signal, and the post-operational amplifier clamps outputting of the control signal.

2. The electronic component real-time protection and monitoring notification system according to claim 1, wherein the output end and the negative end of the post-operational amplifier are connected to each other.

3. The electronic component real-time protection and monitoring notification system according to claim 1, wherein when the monitoring operational amplifier of the positive circuit or the negative circuit operates to determine the difference value between the secondary threshold value and the secondary measurement value to be substantially larger than zero such that the diode of the positive circuit or the negative circuit is forward-biased, and the photocoupler of the positive circuit or the negative circuit is turned off.

4. The electronic component real-time protection and monitoring notification system according to claim 1, further comprising a primary differential amplifier, wherein the primary differential amplifier is connected to the electronic component and a port of the positive end of the pre-operational amplifier that receives the primary threshold value, and the primary differential amplifier converts polarity of the primary measurement value to be opposite to polarity of the primary threshold value.

5. The electronic component real-time protection and monitoring notification system according to claim 1, wherein each of the positive circuits and each of the negative circuits are respectively connected to a positive differential amplifier and a negative differential amplifier, both the positive differential amplifier and the negative differential amplifier are connected to the electronic component, and both the positive differential amplifier and the negative differential amplifier convert polarity of each of the secondary measurement values to be opposite to polarity of the secondary threshold value.

6. The electronic component real-time protection and monitoring notification system according to claim 1, wherein the primary measurement value is a primary parameter for measuring the electronic component, each of the secondary measurement values is a secondary parameter for measuring the electronic component, and the primary parameter is different from each of the secondary parameters.

7. The electronic component real-time protection and monitoring notification system according to claim 6, wherein one of the positive circuit and the negative circuit is selected for operation according to polarity of the corresponding secondary parameter.

8. The electronic component real-time protection and monitoring notification system according to claim 6, wherein the secondary parameters are different from each other.

9. The electronic component real-time protection and monitoring notification system according to claim 6, wherein the secondary parameter is a temperature value, the electronic component real-time protection and monitoring notification system further comprises a thermocouple converter, and the thermocouple converter is connected between the electronic component and the positive circuit or between the electronic component and the negative circuit, in order to convert the temperature value to an electric signal same as the secondary threshold value.

10. The electronic component real-time protection and monitoring notification system according to claim 6, wherein the primary parameter or the secondary parameter is a current value, the electronic component real-time protection and monitoring notification system further comprises a current-to-voltage converter, the current-to-voltage converter is connected between the electronic component and the positive circuit, between the electronic component and the negative circuit, or between the electronic component and the primary controller, in order to convert the current value into an electric signal same as the secondary threshold value or the primary threshold value.

11. The electronic component real-time protection and monitoring notification system according to claim 1, wherein the monitoring notifications are independent of each other.

12. The electronic component real-time protection and monitoring notification system according to claim 1, further comprising a microprocessor, wherein the microprocessor is connected to the primary controller and connected to the photocouplers of the positive circuit and the negative circuit of each of the protection notifiers.

13. The electronic component real-time protection and monitoring notification system according to claim 12, wherein when the microprocessor receives the monitoring notification, the microprocessor sends a stop signal to the primary controller, and the post-operational amplifier stops outputting the control signal.
